(19) United States
(12) Patent Application Publication
(10) Pub. No.: US 2002/0075748 A1
(43) Pub. Date: Jun. 20, 2002

(54) Input circuit for an integrated memory

(76) Inventors: Herbert Benzinger, Munchen (DE); Ralf Schneider, Munchen (DE); Norbert Wirth, Unterschleissheim (DE)

Correspondence Address: LERNER AND GREENBERG, P.A., Post Office Box 2480, Hollywood, FL, 33022-2480, US

(21) Appl. No.: 09/994,201

(22) Filed: Nov. 26, 2001

(30) Foreign Application Priority Data
Nov. 24, 2000 (DE) 100 58 324.5

(51) Int. Cl. G11C 8/18

(52) U.S. Cl. 365/233; 365/194

(57) ABSTRACT

An input circuit for an integrated memory is described. The input circuit for the integrated memory has a signal input line, a memory element, and a clock recovery unit with which a clock signal is generated from the input signal on the signal input line so that the input signal can be read into the memory element using the clock signal which is generated. A further input circuit is described which contains an oscillator. The oscillator generates a clock signal that can be synchronized with the input signal, it being possible to read the input signal into the memory element using the clock signal which is generated.

### BACKGROUND OF THE INVENTION

### Field of the Invention

The invention relates to an integrated memory having a signal input line and a memory element.

Conventional memory modules usually receive different types of input signals, for example control signals, address signals and data signals. The input signals are usually read into the memory in parallel and in synchronism with one or a plurality of clock signals. The input signals are transferred here into a memory element with one edge of a clock signal, the input signal always having to be applied at a specific time before a clock edge (setup time) and still has to be applied for a certain time after the clock edge (hold time) in order to transfer the input signal correctly into the memory element, for example into a latch. The setup and hold time as well as shifts in timing between the input signals limit the clock frequency because a clock signal is frequently to be used to reliably transfer a plurality of input signals into a latch, for example.

In one optimum case, an input signal is sampled at a time that ideally lies in the center of the time range in which the input signal is applied. When there are shifts between the clock signal and an input signal it is possible for the input signal to be sampled not in the center but rather at a time that lies closer to the start and end of the period of validity of the signal. This can lead to a situation in which the necessary setup and/or hold times are undershot and the input signal can therefore not be reliably transferred into a latch, for example.

### SUMMARY OF THE INVENTION

It is accordingly an object of the invention to provide an input circuit for an integrated memory which overcomes the above-mentioned disadvantages of the prior art devices of this general type, which makes it possible, in particular, for the input signals to be transferred quickly and for the reading-in speed of signals into the integrated memory to be increased.

With the foregoing and other objects in view there is provided, in accordance with the invention, an input circuit for an integrated memory. The input circuit contains a signal input line for an input signal, a memory element, and a clock recovery unit connected to the signal input line and coupled to the memory element. The clock recovery unit generates a clock signal from the input signal on the signal input line.

The signal input line is connected to the memory element in order to read the input signal into the memory element under control of the clock signal generated.

According to the invention, the input circuit is provided for the integrated memory. The input circuit contains the signal input and the memory element. Furthermore, the clock recovery unit is provided to which the signal input line is connected. The clock recovery unit is used to generate the clock signal from the input signal on the signal input line. The input signal can be read into the memory element using the clock signal that is generated in this way. The data item which is read into the memory element can then also be written into the integrated memory at predefined times under the control of the clock signal.

Such an input circuit has the advantage that an individual clock signal can be generated from each input signal, the clock signal then being used to read the input signal into the memory element, for example a latch or the like. The necessity to synchronize the input signals with one another in such a way that they can be transferred into memory elements using an individual clock signal is eliminated. In this way, it is possible, for example, to reduce the influence of propagation time effects on setup and hold times.

Moreover, it is advantageous that as a result it is possible to reduce the probability of faults during the transfer of the input signals, such as occur, for example, when the clock signal and the input signal are offset with respect to one another. Because, according to the invention, the clock signal for transferring the input signal into the memory element is generated in each case from the input signal itself, the respective clock signal is thus always matched to the input signal. The clock signal is preferably provided with a pulse duty factor of approximately 50:50. Because the clock signal is synchronized with the signal changeovers of the input signal, the next edge of the clock signal, after approximately half a clock cycle, is preferably used to transfer the data into the memory element. At this time, the data is reliably applied and the requirements in terms of setup time and hold time are fulfilled.

Furthermore, with the input circuit according to the invention it is possible to reduce the number of inputs in an integrated memory because additional clock signal input lines can be dispensed with.

According to one further preferred embodiment, there is provision for the clock recovery unit to have a first pulse generator and a second pulse generator. These are each connected to a phase detector. The signal input line is connected to an input of the first pulse generator in order to generate a pulse signal when there is a signal changeover. The phase detector is connected to an integrator so that the integrator outputs a control voltage to a voltage-controlled oscillator circuit as a function of a phase angle between the generated pulse signal of the first pulse generator and a generated pulse signal of the second pulse generator. An output of the voltage-controlled oscillator circuit is fed back to an input of the second pulse generator and it constitutes the clock signal for the respective input signal.

The clock recovery unit is a phase-locked loop circuit.

With the circuit it is advantageously possible to ensure that the clock signal is continuously adapted to the clock on which the input signals are based. If the input signals happen to be asynchronous with respect to the clock signal that is used as the basis, the circuit according to the invention is capable of generating a clock signal that is adapted to the changed input signals. In this way, it is possible to obtain an input circuit which can be adapted in a very flexible way to the input signals which arrive, as a result of which very high frequencies are possible when reading in input signals.

In accordance with an added feature of the invention, an inverter is provided and has an input connected to the output of the voltage-controlled oscillator circuit and an output connected to the memory element.

In accordance with a further embodiment of the invention, there is provision for the input circuit to have an oscillator which generates a clock signal independently of an external clock, it being possible to synchronize the clock signal with the input signal. The input signal is read into the memory element using the clock signal generated by the oscillator. In this way, the maximum achievable frequency is dependent only on the stability of the clock of a device that provides the input signals and of the oscillator. An uninterrupted data transmission is possible if the initialization and synchronization of the oscillator with an external clock signal are carried out during times in which no data transmission takes place, for example initialization times and/or refresh times. Synchronization can also be performed using the input data if, for example, a specific input data format is selected, for example a format which provides frequent changes of state of the input data.

Other features which are considered as characteristic for the invention are set forth in the appended claims.

Although the invention is illustrated and described herein as embodied in an input circuit for an integrated memory, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block circuit diagram of an embodiment of a PLL circuit for generating an internal clock signal according to the invention;

FIG. 2 is a circuit diagram of an exemplary embodiment of a first pulse generator;

FIG. 3 is a circuit diagram of an exemplary embodiment of a second pulse generator;

FIG. 4 is a circuit diagram of an integrator; and

FIG. 5 is a circuit diagram of an input circuit in which the internal clock signal is generated by an oscillator.

### DESCRIPTION OF THE PREFERRED EMBODIMENTS

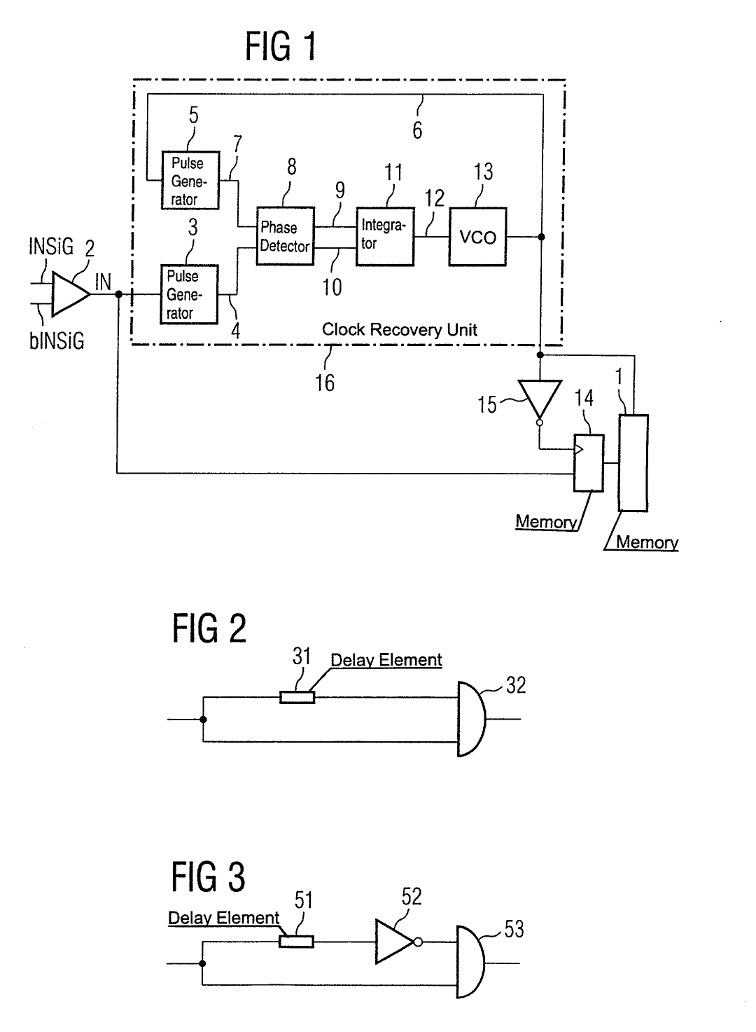

Referring now to the figures of the drawing in detail and first, particularly, to FIG. 1 thereof, there is shown an input circuit for an integrated memory 1 having a clock recovery unit 16. The clock recovery unit 16 receives an input signal IN and generates a clock signal for transferring the input signal IN into a latch 14 from the input signal IN. Further input signals are received on input signal lines INSIG and bINSIG and are differential input signals. The signals are fed to a driver circuit 2. The non-differential input signal IN is present at an output of the driver circuit 2. The input signal IN is fed to a first pulse generator 3 that generates a pulse signal on a first line 4 at each rising and falling edge of the input signal IN. A second pulse generator 5 is provided to whose input a clock signal generated by the recovery unit 16 is fed back via a clock signal line 6, and generates a pulse signal on a second line 7 with each rising edge of the clock signal. The pulse signals on the first and second lines 4, 7 are fed to a phase detector 8 which detects a phase shift between the pulse signals of the first pulse generator 3 and the pulse signal of the second pulse generator 5, and outputs a positive phase shift as a pulse signal on a first phase line 9 and a negative phase shift on a second phase line 10.

The phase lines 9, 10 are connected to an integrator 11 that, depending on whether a positive or negative phase shift is present, brings about a rise or fall in a control voltage applied to an integrator line 12. The control voltage on the integrator line 12 is conducted to a voltage-dependent oscillator 13. The oscillator 13 outputs the clock signal with a preferred pulse duty factor of 50:50, a frequency of the clock signal is increased when the control voltages rise, and the frequency of the clock signal is decreased when the control voltages drop. The clock signal is output onto the clock signal line 6 by the voltage-dependent oscillator 13, and fed back to the second pulse generator 5 as described above.

In the embodiment illustrated, the clock signal on the clock signal line 6 is adjusted again with respect to the input signal IN whenever an edge of the input signal IN occurs, and is synchronized in this way. That is to say the clock signal is adapted to the input signal current in such a way that the rising edge of the clock signal corresponds approximately to a signal changeover of the input signal.

The output of the driver circuit 2 is connected to an input of a latch 14. The oscillator 13 is connected via an inverter 15 to a control input of the latch 14. The input signal IN is transferred into the latch 14 using a positive clock edge of the clock signal. The positive clock edge of the clock signal is approximately chronologically synchronous with a changeover of the input signal IN. Because a transfer of the input signal IN into the latch 14 requires a specific setup time and hold time, it is beneficial to allow the transfer of the input signal IN into the latch 14 to take place at a time which is as far as possible from the times of a possible changeover of the input signal IN. For this reason, the inverter 15 that reverses the falling edge of the clock signal is provided on In the clock signal line 6. Because the falling edge of the clock signal occurs approximately in the center between the fastest possible successive signal changeovers of the input signal when a pulse duty factor of 50:50 is preferably provided, the inverted falling edge of the generated clock signal can be used to read the input signal IN into the latch 14. With the input signal IN described it is possible for a separate clock signal with which the input signal IN is read into the latch 14, to be generated from an input signal.

The clock signal on the clock signal line 9 is also connected to the memory 1 so that a content in the latch 14 can be read into the memory 1 in synchronism with the clock signal, for example at a next clock edge. In this way, an asynchronous input signal can be assigned to a clock signal, the clock signal being used to read the input signal into the memory 1.

The first pulse generator 3 is shown as a block circuit diagram in FIG. 2. It contains a delay element 31 and an exclusive-OR gate 32. The input signal IN is applied to the inputs of the pulse generator 3, once directly and a further time delayed by the delay element 31, at the exclusive OR gate 32. With such a pulse generator circuit it is possible to generate a pulse at each edge that occurs, rising and falling edges, of the input signal IN.

FIG. 3 shows a block circuit diagram of the second pulse generator 5 which has a signal delay element 51, an inverter 52 and an AND gate 53. The clock signal that is generated by the voltage-controlled oscillator 13 is applied to the input of the pulse generator via the clock signal line 6. A pulse signal with the frequency of the clock signal generated by the voltage-dependent oscillator 13 is applied to the output of the AND gate 53. The pulse generator circuit is used to generate a pulse at each rising edge of the clock signal, which pulse is fed to the phase detector 8.

If the phase detector 8 detects a positive phase shift between the pulse generated by the first pulse generator 3 and the pulse signals generated by the second pulse generator 5, the phase detector 8 outputs a pulse signal on the first phase line 9. If the phase shift is negative, a pulse signal is generated on the second phase line.

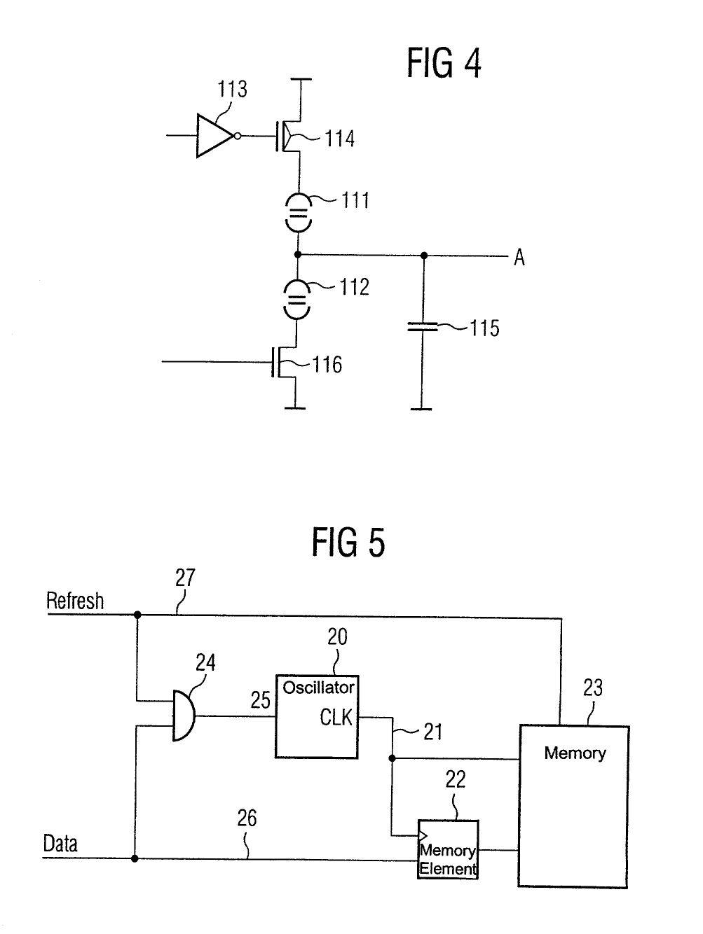

The pulse signals that are generated in the phase detector 8 are fed to an integrator 11, as shown in FIG. 4.

The integrator 11 has two power sources 111, 112 which are switched on depending on whether the phase detector 8 has detected a positive phase shift or a negative phase shift. When a positive phase shift is detected, a p-type channel transistor 114 is switched on for the duration of the pulse on the first phase line 9 by an inverter 113, in response to which the power source 111 is activated and charge can flow to the power source 111. The charge charges a capacitor 115, as a result of which a voltage rises at an output A of the integrator 11. The pulse with the defined duration causes the voltage at the output A to increase only incrementally. If a negative phase shift is detected, a pulse signal with a defined duration from the phase detector 8 is applied to the n-type channel transistor 116. The latter switches on the flow of current to the power source 112, as a result of which the capacitor 115 is made to discharge. As a result, the voltage at the output A decreases incrementally by a specific absolute value. The voltage at the output A is fed to the voltage-dependent oscillator 13 whose oscillatory frequency rises if the voltage at its input rises and whose oscillatory frequency decreases if the voltage at its input decreases.

FIG. 5 illustrates a possible further embodiment of the invention. The input circuit contains an oscillator 20 with a clock input 25 by which the oscillator 20 can be synchronized with a reference clock that is present. The oscillator 20 generates a clock signal CLK on the clock signal line 21 that is connected to a control input of a memory element 22 and a memory 23. The clock signal CLK can be used to transfer the input signal on an input data line 26 into the memory element 22, for example a flip-flop. The data contained in the memory element 22 can then be read into the memory 23, also under the control of the generated clock signal CLK. In order to synchronize the input signals and the clock signal which is generated internally in the oscillator 20 with one another, there is provision for the oscillator 20 to be synchronized with an external reference signal during the refresh cycles of the memory 23, i.e. while the contents stored in the memory 23 are being refreshed, in order to avoid data loss due to charges flowing away in the memory capacitors there. The refresh cycle is indicated by a refresh signal on a refresh line 27. The external reference signal is applied to the input data line 26 from an external source during a refresh cycle. The input data line 26 is connected to the clock input 25 of the oscillator 20 via an AND gate 24 SO that it is present for synchronization only if the refresh signal indicates a refresh mode. In this way, it is possible to avoid having to provide additional clock inputs for synchronization on a memory module. As a result, a saving can be made in terms of external housing ports, enabling the size of the housing to be kept small or to be reduced. The refresh mode is cyclically repeated at certain time intervals so that the clock signal generated by the oscillator 20 on the clock signal line 21 is regularly re-synchronized with the reference signal that is supplied externally.

The features of the invention which are disclosed in the preceding description, the claims and the drawings may be essential for the implementation of the various embodiments of the invention, both individually and in any desired combination.

We claim:

1. An input circuit for an integrated memory, comprising:
a signal input line for an input signal;
a memory element; and
a clock recovery unit connected to said signal input line and coupled to said memory element, said clock recovery unit generating a clock signal from the input signal on said signal input line, said signal input line connected to said memory element in order to read the input signal into said memory element under control of the clock signal generated.

2. The input circuit according to claim 1, wherein said clock recovery unit contains a phase-locked loop circuit.

3. The input circuit according to claim 1, wherein:
said clock recovery unit has a voltage-controlled oscillator circuit with an output, a first pulse generator with an input, a second pulse generator with an input, and a phase detector connected to said first and second pulse generators, said signal input line connected to said input of said first pulse generator in order to generate a first pulse signal at a signal changeover;
said second pulse generator generating a second pulse signal;
said clock recovery unit having an integrator connected to said phase detector in such a way that said integrator outputs a control voltage to said voltage-controlled oscillator circuit in dependence on a phase angle between the first pulse signal generated by said first pulse generator and the second pulse signal generated by said second pulse generator; and
the clock signal generated from the input signal is present at said output of said voltage-controlled oscillator circuit, the clock signal being fed back to said input of said second pulse generator.

4. The input circuit according to claim 3, including an inverter having an input connected to said output of said voltage-controlled oscillator circuit and an output connected to said memory element.

5. An input circuit for an integrated memory, comprising:
a signal input line for an input signal;
a memory element connected to said signal input line and receiving the input signal; and
an oscillator connected to said memory element and generating a clock signal with which the input signal can be synchronized, it being possible to read the input signal into said memory element under control of the clock signal generated.

6. The input circuit according to claim 5, wherein said oscillator is embodied in such a way that said oscillator is synchronized during at least one of initialization times and refresh times of the integrated memory.
